(19) United States
(12) Patent Application Publication
(10) Pub. No.: US 2021/0302815 A1
(43) Pub. Date: Sep. 30, 2021

(54) PROJECTOR

(71) Applicant: SEIKO EPSON CORPORATION, Tokyo (JP)

(72) Inventor: Hiroaki YANAI, Azumino-shi (JP)

(73) Assignee: SEIKO EPSON CORPORATION, Tokyo (JP)

(21) Appl. No.: 17/212,667

(22) Filed: Mar. 25, 2021

(30) Foreign Application Priority Data
Mar. 26, 2020 (JP) 2020-055585

(51) Int. Cl. G03B 21/16; G03B 21/20; H05K 7/20

(52) U.S. Cl. CPC G03B 21/16; G03B 21/2013; H05K 7/2039; H05K 7/20136; G03B 21/204

(57) ABSTRACT

A projector includes a light source apparatus including a first light source section, a wavelength converter and a first cooling section cooling the first light source section. The wavelength converter has a first end surface and a second end surface that face each other and a first side surface and a second side surface that intersect the first and second end surface and face each other and output the second light via the first end surface in a light exiting direction. The first and second end surfaces are smaller than the first and second side surfaces in terms of area. The first light source section is at the first side surface. The first light source section is between the wavelength converter and the first cooling section is perpendicular to the light exiting direction.

The present application is based on, and claims priority from JP Application Serial Number 2020-055585, filed Mar. 26, 2020, the disclosure of which is hereby incorporated by reference herein in its entirety.

### BACKGROUND

### 1. Technical Field

The present disclosure relates to a projector.

### 2. Related Art

In recent years, there is proposed a projector using a solid-state light source, such as a semiconductor laser diode, as the light source of the projector in place of a related-art discharge light source, such as a high-pressure mercury lamp and a metal halide lamp. Using a solid-state light source as the light source attempts to prolong the life of the projector and increase the luminance of the light from the projector.

For example, the projector described in JP-2018-169427 uses a light source apparatus including a quadrangular columnar phosphor containing phosphor particles and a plurality of semiconductor lasers that each output blue light. The plurality of semiconductor lasers are arranged along the longitudinal side surfaces of the phosphor that face each other. The side surfaces facing each other correspond to light incident surfaces. The blue light emitted from the plurality of semiconductor lasers are converted by the phosphor particles in the phosphor, and the converted light exits in the form of yellow light via an end surface of the phosphor. The end surface is a quadrangular column end surface that intersects the side surfaces and corresponds to a light exiting surface.

Heat-sink-shaped cooling members are disposed at side surfaces of the phosphor that differ from the light incident surfaces, where the semiconductor lasers are disposed.

JP-2018-169427 does not, however, disclose a method for cooling the light source apparatus in the projector, and the size of the projector may undesirably increase depending on the cooling method. In detail, to cool the semiconductor lasers, which are each a heat generating source, it is effective to deliver cooling air toward the rear surface of each of the semiconductor lasers that is the surface opposite from the light exiting surface thereof. However, since the semiconductor lasers are disposed at the side surfaces of the phosphor that face each other, two cooling fans are so disposed as to face each other with the phosphor located therebetween. In the configuration described above, the phosphor and the two cooling fans are linearly arranged, resulting in an increase in the size of the projector. Further, the two cooling fans take in air in opposite directions, and it is therefore necessary to provide two intake paths, which can lead to another cause of the increase in the size of the projector.

That is, an object of the present disclosure is to provide a projector that is compact and has satisfactory cooling efficiency.

### SUMMARY

A projector according to an aspect of the present disclosure includes a light source apparatus including a first light source section including a first light source that emits first light that belongs to a first wavelength band, a wavelength converter that contains a phosphor and converts the light emitted from the first light source section into second light that belongs to a second wavelength band different from the first wavelength band, and a first cooling section that cools the first light source section. The wavelength converter has a first end surface and a second end surface that face each other and a first side surface and a second side surface that intersect the first end surface and the second end surface and face each other and outputs the second light via the first end surface in a light exiting direction. The first end surface and the second end surface are smaller than the first side surface and the second side surface in terms of area. The first light source section is disposed at the first side surface. The first light source section is disposed between the wavelength converter and the first cooling section in a first direction perpendicular to the light exiting direction.

### BRIEF DESCRIPTION OF THE DRAWINGS

FIG. 1 is a schematic configuration diagram showing a projector according to a first embodiment.

FIG. 2 is a schematic configuration diagram of an illuminator.

FIG. 3A is a side view of a first light source apparatus.

FIG. 3B is a rear view of the first light source apparatus.

FIG. 3C is a plan view of the first light source apparatus.

FIG. 4A is a plan view showing the configuration for cooling the projector.

FIG. 4B is a side view showing the configuration for cooling the projector.

FIG. 5A is a plan view of a first light source apparatus according to a second embodiment.

FIG. 5B is a rear view of the first light source apparatus.

### DESCRIPTION OF EXEMPLARY EMBODIMENTS

### First Embodiment

### Overview of Projector

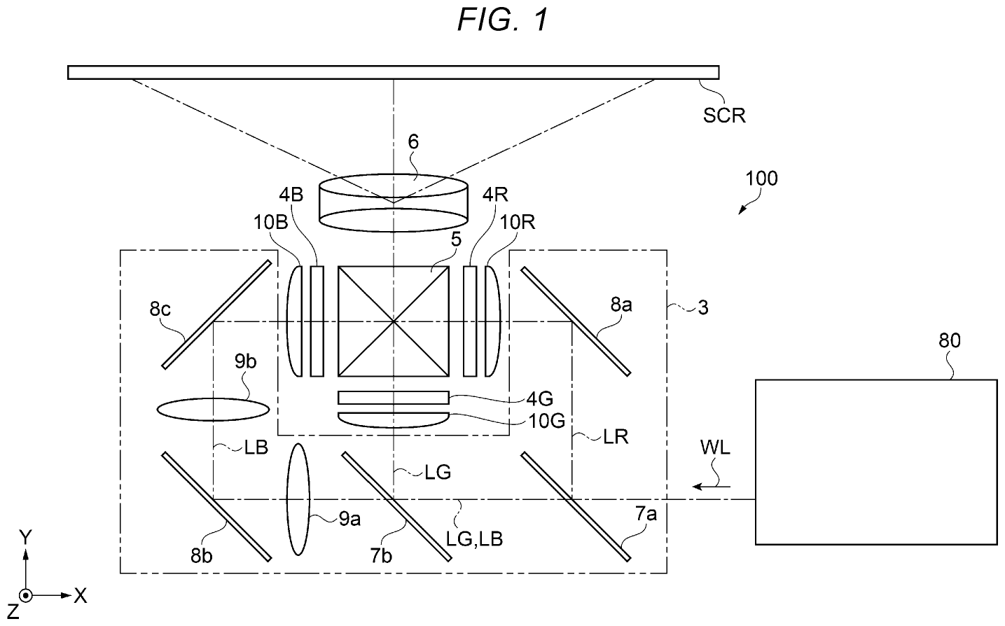

FIG. 1 is a schematic configuration diagram of a projector according to the present embodiment.

A projector 100 is a projection-type image display apparatus that projects and displays color video images on a screen SCR, which is a projection receiving surface.

The projector 100 includes an illuminator 80, a color separation system 3, light modulators 4R, 4G, and 4B, a light combining system 5, and a projection system 6.

The illuminator 80 is an illuminator that radiates white illumination light WL. A specific configuration of the illuminator 80 will be described later.

The color separation system 3 separates the illumination light WL from the illuminator 80 into red light LR, green light LG, and blue light LB. The light modulators 4R, 4G, and 4B modulate the red light LR, the green light LG, and the blue light LB, respectively, in accordance with image information to form image light fluxes corresponding to the respective colors. The light combining system 5 combines the color image light fluxes from the light modulators 4R, 4G, and 4B with one another. The projection system 6 projects the combined image light flux from the light combining system 5 toward the screen SCR.

The color separation system 3 includes a first dichroic mirror 7a, a second dichroic mirror 7b, a first reflection mirror 8a, a second reflection mirror 8b, a third reflection mirror 8c, a first relay lens 9a, and a second relay lens 9b.

The first dichroic mirror 7a separates the illumination light WL emitted from the illuminator 80 into the red light LR and the mixture of the green light LG and the blue light LB. That is, the first dichroic mirror 7a is so characterized as to reflect the red light LR and transmits the green light LG and the blue light LB.

The second dichroic mirror 7b separates the mixture of the green light LG and the blue light LB into the green light LG and the blue light LB. That is, the second dichroic mirror 7b is so characterized as to reflect the green light LG and transmits the blue light LB.

The first reflection mirror 8a is disposed in the optical path of the red light LR and reflects the red light LR reflected off the first dichroic mirror 7a toward the light modulator 4R. The second reflection mirror 8b and the third reflection mirror 8c are disposed in the optical path of the blue light LB and guide the blue light LB having passed through the second dichroic mirror 7b toward the light modulator 4B. The second dichroic mirror 7b reflects the green light LG toward the light modulator 4G.

The first relay lens 9a is disposed in the optical path of the blue light LB on the downstream of the second dichroic mirror 7b. The second relay lens 9b is disposed in the optical path of the blue light LB on the downstream of the second reflection mirror 8b. The first relay lens 9a and the second relay lens 9b compensate optical loss of the blue light LB resulting from the fact that the optical path length of the blue light LB is longer than the optical path lengths of the red light LR and the green light LG.

The light modulators 4R, 4G, and 4B are each formed of a liquid crystal panel. The light modulators 4R, 4G, and 4B modulate the red light LR, the green light LG, and the blue light LB in accordance with image information while transmitting the red light LR, the green light LG, and the blue light LB to form the image light fluxes corresponding to the respective colors. Polarizers (not shown) are disposed on the light incident side and the light exiting side of each of the light modulators 4R, 4G, and 4B.

Field lenses 10R, 10G, and 10B, which parallelize the red light LR, the green light LG, and the blue light LB to be incident on the light modulators 4R, 4G, and 4B, respectively, are provided on the light incident side of the light modulators 4R, 4G, and 4B.

The light combining system 5 is formed, for example, of a cross dichroic prism. The light combining system 5 combines the image light fluxes from the light modulator 4R, 4G, and 4B with one another and causes the combined full-color image light flux toward the projection system 6.

The projection system 6 is formed of a projection lens group. The projection system 6 enlarges the combined image light flux from the light combining system 5 and projects the enlarged image light flux toward the screen SCR. That is, the projection system 6 projects the image light flux formed of the image light fluxes modulated by the light modulators 4R, 4G, and 4B and combined with one another by the light combining system 5 on the screen SCR. Enlarged color video images are thus projected on the screen SCR.

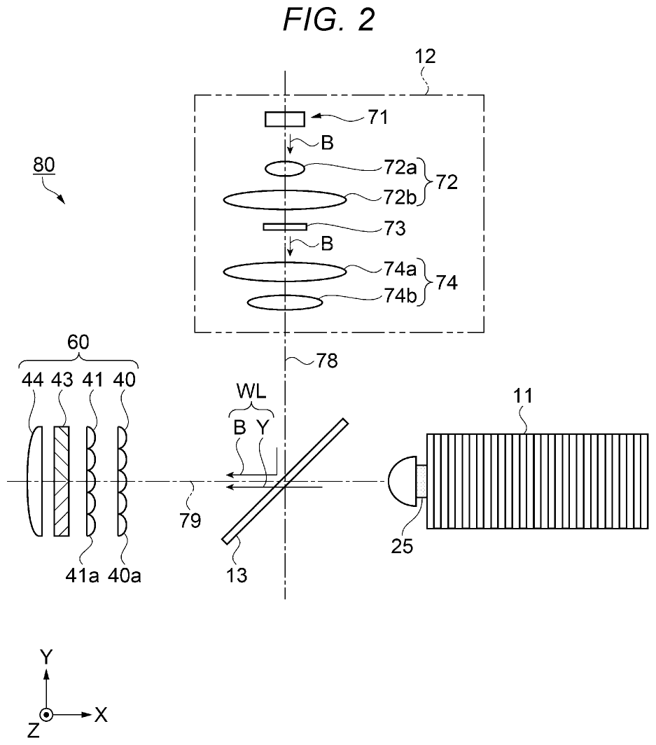

FIG. 2 shows a schematic configuration of the illuminator.

The illuminator 80 is formed, for example, of a first light source apparatus 11, a second light source apparatus 12, a dichroic mirror 13, and a uniform illumination system 60.

The first light source apparatus 11 includes a semiconductor laser as the light source, converts blue light emitted from the semiconductor laser in a wavelength converter 25, and outputs yellow fluorescence Y. The first light source apparatus 11 may instead be configured to output the white light WL. When the first light source apparatus 11 outputs the white light WL, the second light source apparatus 12 and the dichroic mirror 13 can be omitted. The first light source apparatus 11 will be described later in detail.

The second light source apparatus 12 includes a light source 71, a light collection system 72, a scattering plate 73, and a collimation system 74.

The light source 71 uses a semiconductor laser that outputs blue light B, as the light source in the first light source apparatus 11 does. The light source 71 may be formed of one semiconductor laser or a plurality of semiconductor lasers. The light source 71 may instead be formed of an LED (light emitting diode).

The light collection system 72 includes a first lens 72a and a second lens 72b. The light collection system 72 collects the blue light B emitted from the light source 71 to a spot on the scattering plate 73 or in the vicinity thereof. The first lens 72a and the second lens 72b are each formed of a convex lens.

The scattering plate 73 scatters the blue light B from the light source 71 to produce blue light B having a light orientation distribution close to the light orientation distribution of the fluorescence Y emitted from the first light source apparatus 11. The scattering plate 73 can, for example, be a ground glass plate made of optical glass.

The collimation system 74 includes a first lens 74a and a second lens 74b. The collimation system 74 substantially parallelizes the light having exited out of the scattering plate 73. The first lens 74a and the second lens 74b are each formed of a convex lens.

The dichroic mirror 13 is so disposed in the optical path from the first light source apparatus 11 to the uniform illumination system 60 and the optical path from the second light source apparatus 12 to the uniform illumination system 60 as to intersect at 45° each of an illumination optical axis 79 of the first light source apparatus 11 and an optical axis 78 of the second light source apparatus 12. The dichroic mirror 13 reflects the blue light B emitted from the second light source apparatus 12 and transmits the fluorescence Y emitted from the first light source apparatus 11.

The blue light B emitted from the second light source apparatus 12 is reflected off the dichroic mirror 13 and combined with the fluorescence Y having been emitted from the first light source apparatus 11 and having passed through the dichroic mirror 13 into the white illumination light WL. The illumination light WL enters the uniform illumination system 60.

The uniform illumination system 60 includes a first lens array 40, a second lens array 41, a polarization converter 43, and a superimposing lens 44.

The first lens array 40 includes a plurality of first lenses 40a for dividing the illumination light WL into a plurality of sub-light fluxes. The plurality of first lenses 40a are arranged in a matrix in a plane perpendicular to the illumination optical axis 79.

The second lens array 41 includes a plurality of second lenses 41a corresponding to the plurality of first lenses 40a in the first lens array 40. The second lens array 41 along with the superimposing lens 44 brings images of the first lenses 40a in the first lens array 40 into focus in the vicinity of an image formation region of each of the light modulators 4R, 4G, and 4B (FIG. 1). The plurality of second lenses 41a are arranged in a matrix in a plane perpendicular to the illumination optical axis 79.

The polarization converter 43 converts the light having exited out of the second lens array 41 into linearly polarized light. The polarization converter 43 includes, for example, polarization separation films and retardation plates (not shown).

The superimposing lens 44 collects the sub-light fluxes having exited out of the polarization converter 43 and superimposes the collected sub-light fluxes on one another in the vicinity of the image formation region of each of the light modulators 4R, 4G, and 4B.

The description will refer to FIG. 1 again.

The illuminator 80 having the configuration described above outputs the illumination light WL having a substantially uniform illuminance distribution toward the color separation system 3.

### Configuration of First Light Source Apparatus

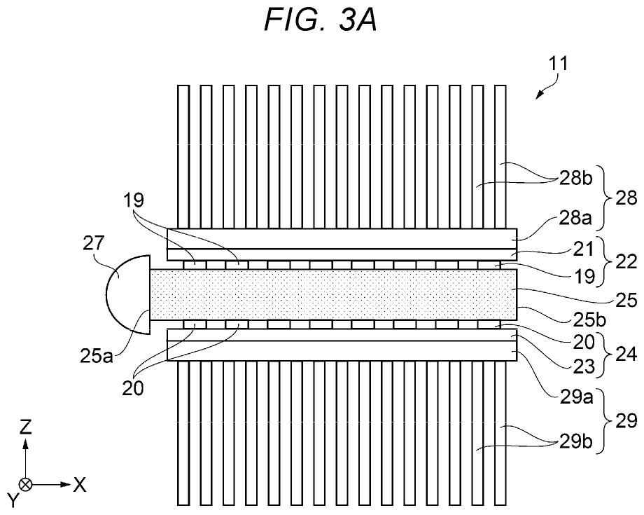

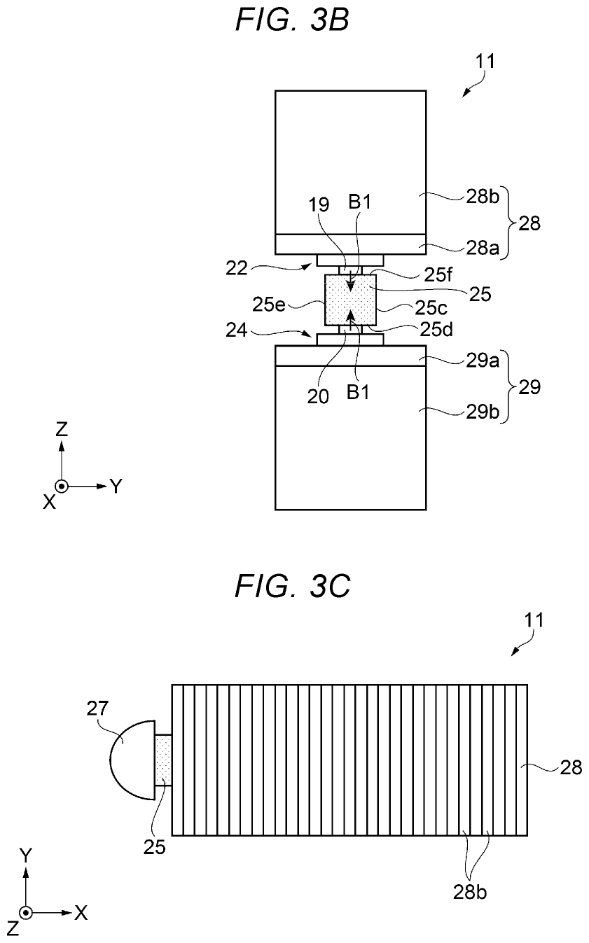

FIG. 3A is a side view of the first light source apparatus. FIG. 3B is a rear view of the first light source apparatus. FIG. 3C is a plan view of the first light source apparatus.

The first light source apparatus 11 includes the wavelength converter 25, a first light source section 22, a second light source section 24, a first cooling section 28, a second cooling section 29, a pickup lens 27, and other components.

The wavelength converter 25 has a columnar box-like shape in a preferable example, and the first light source section 22 is disposed at a side surface 25f, as a first side surface, in the longitudinal direction. The second light source section 24 is disposed at a side surface 25d, as a second side surface, which faces the side surface 25f. Aside surface 25c faces a side surface 25e. A first end surface 25a is a light exiting surface, and the pickup lens 27 is disposed at the first end surface 25a. The first end surface 25a faces a second end surface 25b. The first end surface 25a and the second end surface 25b are smaller than the side surface 25f and the side surface 25d in terms of area. In a preferable example, a reflection layer made of metal, such as aluminum, is formed at each of the second end surface 25b, the side surface 25c, and the side surface 25e to prevent light leakage for an increase in light use efficiency. The wavelength converter 25 does not necessarily have a columnar box-like shape and may instead be a rod integrator lens having a light incident surface and a light exiting surface. For example, the wavelength converter 25 may have the shape of a cubic or a decahedron. Still instead, the wavelength converter 25 may have the shape of a quadrangular column formed of trapezoidal side surfaces and oblong end surfaces having an area smaller than those of the trapezoidal side surfaces, such as a tapered rod.

The wavelength converter 25 is a rod integrator lens; phosphor particles in the wavelength converter 25 convert excitation light B1 incident via the side surface 25f and the side surface 25d, and the converted light exits as substantially homogenized fluorescence Y via the first end surface 25a. The wavelength converter 25 contains YAG-based (yttrium-aluminum-garnet-based) phosphor particles as a preferable example.

The phosphor particles may be made of one material or may be a mixture of particles made of two or more types of materials different from one another. It is preferable that the phosphor particles are dispersed in an inorganic binder, such as alumina or sintered with no binder.

The first light source section 22 is formed of first light sources 19, which each output the excitation light B1, which belongs to a first wavelength band, and a substrate 21, on which the plurality of the first light sources 19 are mounted. The substrate 21 has an oblong shape along the side surface 25f of the wavelength converter 25, and the plurality of first light sources 19 are mounted on the substrate 21 along the direction of the long sides of the oblong shape at substantially equal intervals. Electric wires (not shown) that supply drive power for turning on the plurality of first light sources 19 are connected thereto. In a preferable example, the first light sources 19 are each formed of a semiconductor laser that outputs the excitation light B1 formed of laser light as first light that belongs to the first wavelength band. The light that belongs to the first wavelength band corresponds, for example, to light having emitted light intensity that peaks at wavelengths ranging from 430 to 480 nm. As a preferable example, the excitation light B1is light having emitted light intensity that peaks at a wavelength of about 445 nm. The configuration described above is not necessarily employed. For example, a semiconductor laser or an LED that outputs blue laser light having a wavelength of 460 nm may be used.

The second light source section 24 is formed of second light sources 20, which each output the excitation light B1, which belongs to the first wavelength band, and a substrate 23, on which the plurality of the second light sources 20 are mounted. The second light source section 24 differs from the first light source section 22 in that the second light source section 24 is disposed at the side surface 25d of the wavelength converter 25.

The excitation light B1 emitted from the first light source section 22 and the second light source section 24 enters the wavelength converter 25. The wavelength converter 25 converts the excitation light B1 into the fluorescence Y as second light that belongs to a second wavelength band different from the first wavelength band and causes the fluorescence Y to exit via the first end surface 25a in a light exiting direction. In a preferable example, the light that belongs to the second wavelength band corresponds to yellow light having emitted light intensity that peaks at wavelengths ranging from 520 to 580 nm. The second wavelength band only needs to a wavelength band to which yellow light belongs and which ranges from 480 to 700 nm. The light exiting direction used herein is the direction of the optical axis of the fluorescence Y, which exits via the first end surface 25a, and is also the direction of the optical axis of the pickup lens 27 and the direction of a normal to the first end surface 25a.

The first cooling section 28 is a heat sink and is formed, for example, of a base 28a and a plurality of fins 28b. The fins 28b correspond to first fins. In a preferable example, the first cooling section 28 is formed of a heat sink integrated with the plurality of fins 28b produced by cutting a block made of aluminum. The first cooling section 28 only needs to be made of a material having high thermal conductivity, for example, copper, molybdenum, or an alloy thereof. The base 28a, which has a flat-plate-like shape, is fixed via a surface thereof to the rear surface of the substrate 21 of the first light source section 22. In a preferable example, the substrate 21 and the base 28a are bonded and fixed to each other by using an adhesive having high heat resistance and thermal conductivity. The plurality of fins 28b are formed in a combtooth-like shape in FIG. 3A. The fins 28b extend in the axis-Y direction and have a length greater than the width of the wavelength converter 25 and the width of the first light source section 22, as shown in FIG. 3B.

The second cooling section 29 has the same configuration as that of the first cooling section 28. In detail, the second cooling section 29 is a heat sink formed of a base 29a and a plurality of fins 29b. The fins 29b correspond to second fins. The second cooling section 29 is fixed to the rear surface of the substrate 23 of the second light source section 24.

The pickup lens 27 is provided at the first end surface 25a of the wavelength converter 25. The pickup lens 27 is a convex lens, and the flat surface of the pickup lens 27 is bonded and fixed to the first end surface 25a of the wavelength converter 25 via a light transmissive adhesive. The pickup lens 27 has the function of extracting the fluorescence Y that exits via the first end surface 25a. An optical member (not shown), such as a lens, for parallelizing the fluorescence Y having exited out of the pickup lens 27 may be disposed in the downstream of the optical path of the pickup lens 27.

In the thus configured first light source apparatus 11, the pickup lens 27 and the plurality of stripe-like fins 28b of the first cooling section 28 are primarily visible in the plan view, as shown in FIG. 3C. In a side view, the first cooling section 28, the first light source section 22, the wavelength converter 25, the second light source section 24, and the second cooling section 29 are arranged along the axis-Z direction, as shown in FIG. 3A. In other words, the first cooling section 28, the first light source section 22, the wavelength converter 25, the second light source section 24, and the second cooling section 29 are so disposed as to overlaid on each other along the axis-Z direction as a first direction perpendicular to the light exiting direction. In still other words, the first light source section 22 is disposed between the wavelength converter 25 and the first cooling section 28, and the second light source section 24 is disposed between the wavelength converter 25 and the second cooling section 29 along the axis-Z direction as the first direction.

In the first light source apparatus 11, the first light source section 22 and the second light source section 24 form a heat generating source that generates the largest amount of heat, followed by the wavelength converter 25, the first cooling section 28, and the second cooling section 29 in the descending order of the amount of generated heat. In the side view, the heat generating sources described above are so arranged in tandem to be symmetric in the upward/downward direction with respect to the wavelength converter 25 as the center. A large cooling effect is therefore expected by delivering cooling air confronting directly to the first light source apparatus 11 having the state described above.

The description has been made above with reference to the aspect in which the set of the first light source section 22 and the first cooling section 28 and the set of the second light source section 24 and the second cooling section 29 are so disposed as to face each other with the wavelength converter 25 therebetween, but not necessarily, and one of the sets may be omitted. For example, the set of the second light source section 24 and the second cooling section 29 may be omitted. It can be expected that even the configuration described above, in which the first cooling section 28, the first light source section 22, and the wavelength converter 25 are arranged in tandem, can provide a large cooling effect by delivering cooling air confronting directly to the configuration.

### Light Source Apparatus Cooling Configuration in Projector

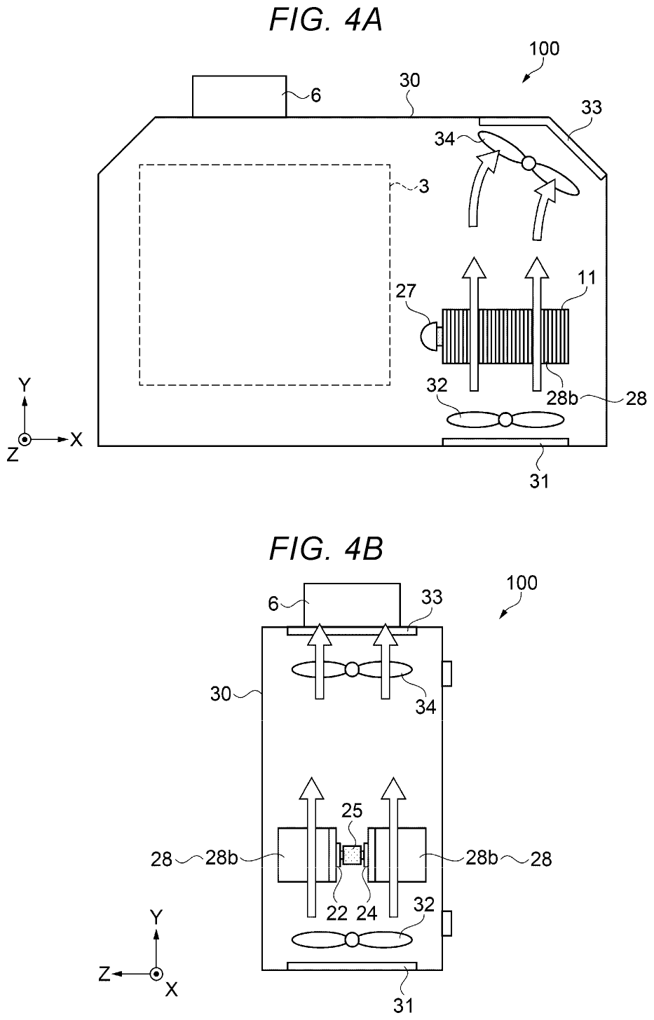

FIG. 4A is a plan view showing the configuration for cooling the projector and corresponds to FIG. 1. FIG. 4B is a side view of the cooling configuration.

An enclosure 30 of the projector 100 has a substantially oblong shape, and an intake port 31 is provided at one of the long edges of the oblong shape of the enclosure 30. The projection system 6, a discharge port 33, and other components are provided at the other long side of the oblong shape of the enclosure 30. The light source apparatus cooling configuration is formed, for example, of a first fan 32 and a second fan 34.

The first fan 32 is an axial fan and is so disposed as to face the intake port 31. The first fan 32 takes in the air outside the enclosure 30 via the intake port 31 and sprays the air in the form of cooling air to the first light source apparatus 11.

The cooling air from the first fan 32 is sprayed to aside surface of the first light source apparatus 11, as shown in FIG. 4B. In this process, the first light source apparatus 11 faces the first fan 32 with the first cooling section 28, the first light source section 22, the wavelength converter 25, the second light source section 24, and the second cooling section 29 arranged as shown in FIG. 3A. The cooling air from the first fan 32 is therefore sprayed confronting directly to the portions of the first light source apparatus 11 that each form a heat generating source.

Further, part of the cooling air passes through the gaps between the plurality of fins 28b of the first cooling section 28 and travels toward the second fan 34, as indicated by the arrows in FIG. 4A. Since the plurality of fins 28b extend along the direction from the cooling air upwind side toward the cooling air downwind side (axis-Y direction) as a second direction that intersects the light exiting direction, the cooling air can pass through the gaps between adjacent fins 28b. The cooling air absorbs heat from the first cooling section 28 when passing through the gaps between adjacent fins 28b. The same holds true for the plurality of fins 29b of the second cooling section 29.

The second fan 34 is an axial fan and is so disposed as to face the discharge port 33. The second fan 34 discharges the air having absorbed the heat when passing through the first light source apparatus 11 out of the enclosure 30 via the discharge port 33. Although not shown, when the second light source apparatus 12 (FIG. 2) is provided, the second light source apparatus 12 is disposed between the first light source apparatus 11 and the second fan 34.

The configuration for cooling the light source apparatus and therearound has been described above, and the cooling path may also serve as the cooling path for the other optical systems. In detail, the light source apparatus cooling path may also serve as the cooling path for the light combining system 5 and the light modulators 4R, 4G, and 4B, which are each a heat generating source other than the light source apparatus. For example, a sirocco fan may spray cooling air to the light combining system 5, and the cooling air exhausted via the light combining system 5 may be discharged by the second fan 34 out of the enclosure 30 via the discharge port 33. In this case, a discharge path is so provided that the exhausted air is directed toward the second fan 34. The cooling paths in the projector 100 can thus be integrated into one cooling path.

As described above, the first cooling section 28 is so disposed as to be overlaid on the wavelength converter 25 and the first light source section 22 in the axis-Z direction as the first direction. Similarly, the second cooling section 29 is so disposed as to be overlaid on the wavelength converter 25 and the second light source section 24 in the axis-Z direction.

The configuration in which the first fan 32 is so disposed as to deliver air in the axis-Y direction as the second direction, which intersects the first direction and the light exiting direction, allows the cooling air to impinge confronting directly on the first cooling section 28, the first light source section 22, the wavelength converter 25, the second light source section 24, and the second cooling section 29 together for efficient cooling.

Therefore, according to the present application, the two light sources can be efficiently cooled by using the compact configuration formed of one first fan 32, unlike in the related-art cooling configuration, in which the two cooling fans are so disposed as to face each other with the phosphor therebetween to cool the two light sources disposed at the surfaces of the phosphor that face each other so that the cooling configuration has a large size.

A projector 100 that is compact and has satisfactory cooling efficiency can therefore be provided.

The first cooling section 28 is provided with the plurality of fins 28b, and the fins 28b extend along the axis-Y direction as the second direction.

The cooling air from the first fan 32 can therefore pass through the gaps between adjacent fins 28b and can absorb the heat from the first cooling section 28 when passing through the gaps. The cooling efficiency is therefore improved.

The first fan 32 is so provided as to deliver air in the second direction, which intersects the first direction.

The cooling air can thus impinge confronting directly on the first cooling section 28, the first light source section 22, the wavelength converter 25, the second light source section 24, and the second cooling section 29 together for more efficient cooling.

Further, the projector 100 includes the enclosure 30, which accommodates the illuminator 80, the color separation system 3, and the light modulators 4. The first fan 32 is so disposed as to face the intake port 31 of the enclosure 30. The projector 100 further includes the second fan 34 so disposed as to face the discharge port 33 of the enclosure 30. The first fan 32, the first light source apparatus 11, and the second fan 34 are arranged in this order along the second direction.

In the configuration described above, the first fan 32 takes in the air outside the enclosure 30 via the intake port 31 and sprays the air in the form of cooling air to the first light source apparatus 11. The second fan 34 discharges the air having passed through the first light source apparatus 11 and absorbed the heat therefrom out of the enclosure 30 via the discharge port 33. Since the cooling air path is substantially linear along the second direction (axis-Y direction) as shown in FIGS. 4A and 4B, the air flow is not greatly hindered, and excellent cooling efficiency is achieved.

A projector 100 that is compact and has satisfactory cooling efficiency can therefore be provided.

The cooling air path is not limited to substantially linear as in a preferably example, and channels can be formed in a single plane perpendicular to the first direction. When the channels are formed in the same plane, the channels can be curved at relatively gentle angles, instead of right-angled channels that bend to an upper or lower plane perpendicular to the plane. Further, the enclosure 30 may be an internal enclosure that accommodates the illuminator 80 or a light source enclosure that accommodates the first light source apparatus.

### Second Embodiment

### Different Configuration of First Light Source

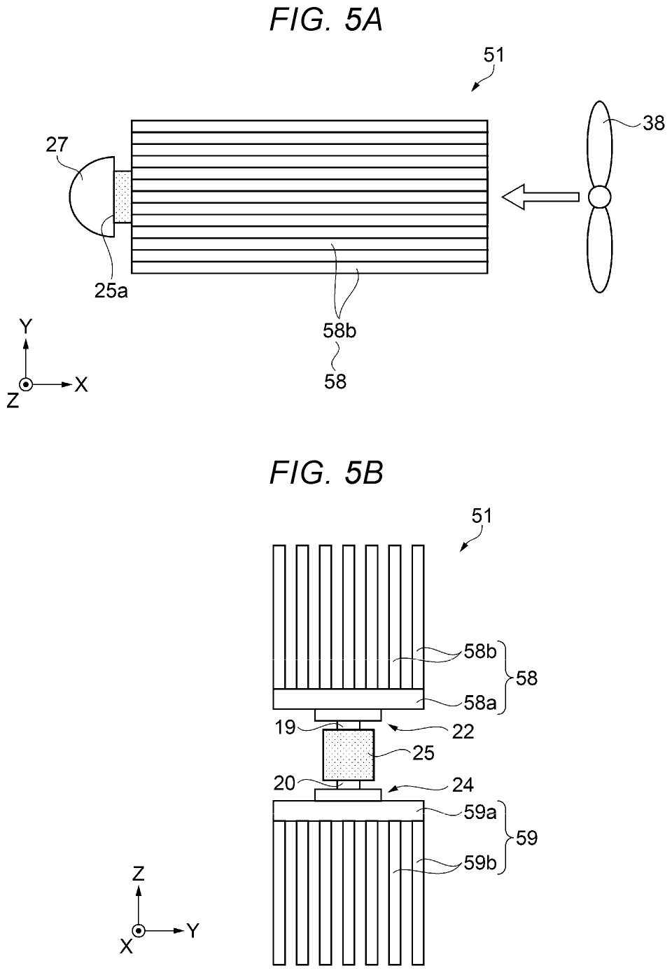

FIG. 5A is a plan view of the first light source apparatus according to the present embodiment and corresponds to FIG. 3C. FIG. 5B is a rear view of the first light source apparatus and corresponds to FIG. 3B.

A first light source apparatus 51 according to the present embodiment differs from the first light source apparatus 11 according to the first embodiment in terms of the direction in which the fins of the cooling sections extend. In detail, the direction in which a plurality of fins 58b of a third cooling section 58 extend is the direction along the axis X. The same holds for a plurality of fins 59b of a fourth cooling section 59. Except for this point, the first light source apparatus 51 is the same as the first light source apparatus 11 according to the first embodiment.

In the configuration described above, a cooling fan 38 is disposed on the opposite side of the first light source apparatus 51 from the pickup lens 27, as shown in FIG. 5A. The third cooling section 58 is so disposed as to be overlaid on the wavelength converter 25 and the first light source section 22 in the axis-Z direction as the first direction, as shown in FIG. 5B. Similarly, the fourth cooling section 59 is so disposed as to be overlaid on the wavelength converter 25 and the second light source section 24 in the axis-Z direction. In the present embodiment, the second direction, which intersects the first direction, is the axis-X direction. That is, in the present embodiment, the second direction is the direction along the light exiting direction.

The configuration in which the fan 38 is so disposed as to deliver air in the axis-X direction as the second direction allows the cooling air to impinge confronting directly on the third cooling section 58, the first light source section 22, the wavelength converter 25, the second light source section 24, and the fourth cooling section 59 together for more efficient cooling.

The third cooling section 58, the first light source section 22, the wavelength converter 25, the second light source section 24, and the fourth cooling section 59 are not necessarily overlaid on each other in the axis-Z direction, and the first or last three of the components described above only need to be overlaid on each other in the axis-Z direction. For example, the set of the second light source section 24 and the fourth cooling section 59 may be omitted. It can be expected that even the configuration described above, in which the third cooling section 58, the first light source section 22, and the wavelength converter 25 are arranged in tandem, can provide a large cooling effect by delivering the cooling air confronting directly to the component described above. A projector that is compact and has satisfactory cooling efficiency can therefore be provided.

### Third Embodiment

### Other Applications

In the embodiments described above, the projector 100 including the three light modulators 4R, 4G, and 4B has been presented by way of example, and the present disclosure is also applicable to a projector that displays color video images via one light modulator. The light modulators may each be a digital mirror device.

The aforementioned embodiments have been described with reference to the case where the first light source apparatus 11 or 51 is incorporated in a projector, but not necessarily. The first light source apparatuses 11 and 51 may each be also used as a lighting apparatus, a headlight of an automobile, and other components.

What is claimed is:

1. A projector comprising
a light source apparatus including
a first light source section including a first light source that emits first light that belongs to a first wavelength band,
a wavelength converter that contains a phosphor and converts the light emitted from the first light source section into second light that belongs to a second wavelength band different from the first wavelength band, and
a first cooling section that cools the first light source section,
wherein the wavelength converter has a first end surface and a second end surface that face each other and a first side surface and a second side surface that intersect the first end surface and the second end surface and face each other and outputs the second light via the first end surface in a light exiting direction,
the first end surface and the second end surface each are smaller than the first side surface and the second side surface in terms of area,
the first light source section is disposed at the first side surface, and
the first light source section is disposed between the wavelength converter and the first cooling section in a first direction perpendicular to the light exiting direction.

2. The projector according to claim 1,
wherein the first cooling section is provided with a plurality of first fins, and
the first fins extend along a second direction that intersects the first direction.

3. The projector according to claim 2,
wherein the second direction intersects the light exiting direction.

4. The projector according to claim 2,
wherein the second direction extends along the light exiting direction.

5. The projector according to claim 1,
wherein the light source apparatus further includes
a second light source section including a second light source that emits the first light that belongs to the first wavelength band, and
a second cooling section that cools the second light source section,
the second light source section is disposed at the second side surface, and
the second light source section is disposed between the wavelength converter and the second cooling section in the first direction.

6. The projector according to claim 5,
wherein the second cooling section is provided with a plurality of second fins, and
the second fins extend along the second direction.

7. The projector according to claim 2, further comprising a first fan that supplies a cooling medium along the second direction.

8. The projector according to claim 7,
further comprising an enclosure that accommodates the light source apparatus,
wherein the first fan is so disposed as to face an intake port of the enclosure,
the projector further comprises a second fan so disposed as to face a discharge port of the enclosure, and
the first fan, the light source apparatus, and the second fan are arranged in a presented order along the second direction.
